(19) United States
(12) Patent Application Publication
(10) Pub. No.: US 2025/0299951 A1
(43) Pub. Date: Sep. 25, 2025

(54) LOW-TEMPERATURE ETCHANT-FREE SELECTIVE EPITAXY OF N-TYPE DOPED SILICON

(71) Applicant: Applied Materials, Inc., Santa Clara, CA (US)

(72) Inventors: Mengjing WANG, Sunnyvale, CA (US); Yi-Chiau HUANG, Fremont, CA (US)

(21) Appl. No.: 18/614,826

(22) Filed: Mar. 25, 2024

(51) Int. Cl. H01L 21/02; C30B 25/04; C30B 25/10; C30B 25/16; C30B 29/06

(52) U.S. Cl. CPC H01L 21/02576; C30B 25/04; C30B 25/10; C30B 25/165; C30B 29/06; H01L 21/0262; H01L 21/02658

(57) ABSTRACT

Methods for low temperature selective deposition of epitaxial silicon-containing films and semiconductor devices incorporating the epitaxial silicon-containing films are provided. The method includes etchant-free selective epitaxy of N-type doped silicon including either a soak in a phosphorous source gas or an antimony seed layer. In one or more implementations, an underlying silicon surface is exposed to a pre-soak process performed by exposing the silicon surface to a phosphorous-containing gas, for example, phosphine gas, for a period of time followed by growing the N-doped epitaxial silicon film by co-flowing silicon sources and antimony sources only. The pre-soak/deposition process can be applied repeatedly to achieve desirable stack thickness. In one or more implementations, a seed layer of antimony-doped silicon is formed by co-flowing silicon and antimony source gases followed by co-flowing silicon source gases, antimony source gases, and phosphorous source gases to grow the N-doped epitaxial silicon film.

### BACKGROUND

### Field

The present disclosure generally relates to the field of semiconductor devices and methods for manufacturing semiconductor devices. More particularly, the disclosure relates to low temperature selective deposition of epitaxial silicon-containing films.

### Description of the Related Art

A typical selective epitaxy process involves a deposition reaction and an etch reaction. The deposition reaction causes an epitaxial layer to be formed on monocrystalline surfaces of a substrate and a polycrystalline and/or amorphous layer to be formed on non-monocrystalline surfaces, for example, a patterned dielectric layer deposited atop the substrate. The etch reaction removes the epitaxial layer and the polycrystalline and/or amorphous layer at different rates, providing a net selective process that can result in deposition of an epitaxial material and limited, or no, deposition of a polycrystalline material and/or amorphous material.

As the critical dimensions of devices continue to shrink, methods of selective epitaxial deposition involve lower processing temperatures (e.g., about 500 degrees Celsius or less). Unfortunately, typical etching gases fail to provide a suitable selective window between the epitaxial layer and the polycrystalline and/or amorphous layer at lower processing temperatures. In addition, current cyclic deposition/etch processes can be complex, difficult to maintain, and have low throughput.

For the foregoing reasons, there is a need for selective epitaxial processes that can be performed at lower temperatures.

### SUMMARY

The present disclosure generally relates to the field of semiconductor devices and methods for manufacturing semiconductor devices. More particularly, the disclosure relates to low temperature selective deposition of epitaxial silicon-containing films.

In one aspect, a method of forming a film on a substrate is provided. The method includes heating a substrate disposed within a processing chamber to a temperature in a range from about 350 degrees Celsius to about 500 degrees Celsius. The method further includes exposing the substrate to a soak process in a phosphorous source gas at a first chamber pressure for a period of time. The method further includes increasing the first chamber pressure to a second chamber pressure. The method further includes exposing the substrate to a deposition gas mixture including a chlorosilane gas and an antimony-containing source gas to deposit a silicon-containing epitaxial layer including antimony on the substrate.

Implementations may include one or more of the following. The first chamber pressure is within a range from about 20 Torr to about 100 Torr and the second chamber pressure is within a range from about 150 Torr to about 300 Torr. Increasing the first chamber pressure to the second chamber pressure purges the phosphorous source gas from the processing chamber. The period of time is within a range from about 20 seconds to about 90 seconds. The phosphorous source gas is phosphine gas. The chlorosilane gas includes dichlorosilane, trichlorosilane, or a combination thereof. The deposition gas mixture further includes silane, disilane, or combination thereof. The method further includes repeating exposing the substrate to the soak process, increasing the first chamber pressure to the second chamber pressure, and exposing the substrate to the deposition gas mixture until a targeted thickness of the silicon-containing epitaxial layer is achieved. The chlorosilane gas is flown at a flow rate in a range from about 500 sccm to about 1,000 sccm and the antimony-containing source gas is flown at a flow rate in a range from about 500 sccm to about 1,000 sccm.

In another aspect, a method of forming a film on a substrate is provided. The method includes heating a substrate disposed within a processing chamber to a temperature in a range from about 350 degrees Celsius to about 500 degrees Celsius. The substrate is exposed to a deposition gas mixture including a chlorosilane gas and an antimony-containing source gas to deposit an antimony doped silicon-containing epitaxial seed layer including antimony on the substrate. The method further includes introducing a phosphorous source gas into the processing chamber. The method further includes exposing the substrate to the deposition gas mixture and the phosphorous source gas to deposit a silicon-containing epitaxial layer including antimony and phosphorous on the substrate.

Implementations may include one or more of the following. The antimony doped silicon-containing epitaxial seed layer has a thickness in a range from about 1 angstrom to about 100 angstroms. The chlorosilane gas includes dichlorosilane, trichlorosilane, or a combination thereof. The antimony-containing precursor is one or a combination of stibine, antimony trichloride, antimony tetrachloride, antimony pentachloride, triphenylantimony, antimony trihydride, antimonytrioxide, antimony pentoxide, antimony trifluoride, antimony tribromide, antimonytriiodide, antimony pentafluoride, triethyl antimony, and trimethyl antimony. The chlorosilane gas in a carrier gas is delivered at a total flow rate in a range from about 3,000 to about 9,000 sccm, the antimony-containing source gas is delivered at a flow rate in a range from about 500 to about 3,000 sccm, and the phosphorous source gas is delivered at a flow rate in a range from about 1 to about 2,000 sccm.

In yet another aspect, a method of forming an epitaxial film on a substrate is provided. The method includes positioning a substrate into a processing chamber, the substrate including a silicon surface and a dielectric surface. The method further includes exposing the substrate to phosphine gas at a temperature in a range from about 350 degrees Celsius to about 500 degrees Celsius at a first chamber pressure within a range from about 20 Torr to about 100 Torr for a period of time. The method further includes increasing the first chamber pressure to a second chamber pressure. The method further includes exposing the substrate to a deposition gas mixture including a chlorosilane gas and an antimony-containing source gas to selectively deposit a silicon-containing epitaxial layer including antimony on the silicon surface.

Implementations may include one or more of the following. The silicon-containing epitaxial layer has an antimony dopant concentration of greater than 3×10²¹ atoms per cubic centimeter. The second chamber pressure is within a range from about 150 Torr to about 300 Torr. Increasing the first chamber pressure to the second chamber pressure purges the phosphorous source gas from the processing chamber. The period of time is within a range from about 20 seconds to about 90 seconds. The phosphorous source gas is phosphine gas and the chlorosilane gas includes dichlorosilane, trichlorosilane, or a combination thereof. The deposition gas mixture further includes silane, disilane, or combination thereof.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, and may admit to other equally effective implementations.

FIG. 1 illustrates a schematic side view of one example of a deposition chamber in accordance with one or more implementations of the present disclosure.

FIG. 2 illustrates an exemplary flow chart of a method for manufacturing a semiconductor device in accordance with one or more implementations of the present disclosure.

FIGS. 3A-3C illustrate view of various stages of manufacturing a semiconductor device in accordance with one or more implementations of the present disclosure.

FIG. 4 illustrates an exemplary flow chart of another method for manufacturing a semiconductor device in accordance with one or more implementations of the present disclosure.

FIGS. 5A-5C illustrate view of various stages of manufacturing a semiconductor device in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure generally relates to the field of semiconductor devices and methods for manufacturing semiconductor devices. More particularly, the disclosure relates to low temperature selective deposition of epitaxial silicon-containing films.

The three-dimensional nature of advance logic architectures, for example, complementary metal-oxide-semiconductor (CMOS) logic and memory scaling, involve growing epitaxial structures in more complex and restrictive geometries composed of an ever increasing different range of materials. In addition, changing demands on epitaxial doping levels and decreasing thermal budgets place additional burdens on traditional selective epitaxial deposition processes. Traditional epitaxial deposition processes have difficulty achieving co-flow selective Si: P or Si: Sb epitaxial deposition at low temperatures (e.g., 550 degrees Celsius or less) because HCl is generally not active at these low temperatures. As a result, traditional epitaxial deposition processes are performed using a cyclic deposition/etch process, which is complicated and time consuming leading to throughput issues. Aspects of the present disclosure provide a selective epitaxial deposition process that is etchant-free and provides the co-flow of chlorosilane precursors with at least one of an antimony-containing precursor and a phosphorous-containing precursor. Aspects of the present disclosure utilize co-flowing of multiple chlorosilane precursors to enable combination of silicon and at least one of phosphorous and antimony in the same matrix using a low-temperature selective process. The deposited epitaxial layer using the epitaxial deposition techniques described not only contains phosphorous and/or antimony but also has a high concentration of activated phosphorous and/or antimony.

Implementations of the present disclosure provide methods, systems, and structures for achieving selective epitaxial deposition at low temperatures, for example, temperatures of 500 degrees Celsius or less or 450 degrees Celsius or less. Implementations of the present disclosure are suitable for logic contact and other applications that involve low-temperature, selective, and high active-dopant epitaxial deposition. In one or more implementations, which can be combined with other implementations a method of low temperature epitaxial deposition is provided. The method is performed at a temperature of 500 degrees Celsius or less. The method includes the use of a higher order silane precursor and/or a higher order chlorosilane precursor, and an n-type dopant precursor selected from an antimony-containing precursor, a phosphorous-containing precursor, an arsenic-containing precursor, or a combination thereof.

The combination of chlorosilane precursors of the present disclosure is utilized to continuously etch the epitaxial layer as it is formed and improves the selectivity of the epitaxial layer as the epitaxial layer is deposited onto a device, for example, a superlattice structure. The epitaxial layer is formed only on the crystalline portions of the structure and not on oxide or non-crystalline surfaces. The antimony-containing precursor lowers the temperature at which the epitaxial layer is deposited and increases the growth rate of the epitaxial layer on the crystalline portions of the structure. The phosphorous-containing precursor dopes the epitaxial layer with phosphorous and enables better adhesion to the crystalline portions of the structure and lowers resistivity. The arsenic containing precursor provides films having a different strain relative to phosphorous doped films at similar dopant levels, which can lead to improved crystallinity.

In one or more implementations of the present disclosure, the N-doped epitaxial silicon film is grown by co-flowing a selection of silicon and N-dopant sources including but not limited to silane, disilane, dichlorosilane, trichlorosilane, tri-ethyl antimony, and phosphine at temperatures below 500 degrees Celsius. The antimony source can selectively activate the underlying silicon surface and enhance the growth rate of the doped epitaxial silicon layer at low temperatures.

In one or more implementations, the N-doped epitaxial silicon film is grown by co-flowing silicon sources and antimony sources only.

In one or more implementations, an underlying silicon surface is exposed to a pre-soak process performed by exposing the silicon surface to a phosphorous-containing gas, for example, phosphine gas, for a period of time followed by growing the N-doped epitaxial silicon film by co-flowing silicon sources and antimony sources only. The pre-soak/deposition process can be applied repeatedly to achieve desirable stack thickness.

In one or more implementations, a seed layer of antimony-doped silicon is formed by co-flowing silicon and antimony source gases followed by co-flowing silicon source gases, antimony source gases, and phosphorous source gases to grow the N-doped epitaxial silicon film.

The etchant-free deposition method described has improved throughput compared to conventional cyclic deposition and etch processes. The etch-free process described is more compatible with various chambers in mass production. The absence of etchant gas in the etchant-free process described enables deposition of an epitaxial film with a high level of dopant, for example, an N-type dopant concentration of greater than 3×10²¹ atoms per cubic centimeter, which is beneficial for resistivity tuning. The improved selectively of the etchant-free process described widens the process window tuning, thus increasing adaptability and feasibility.

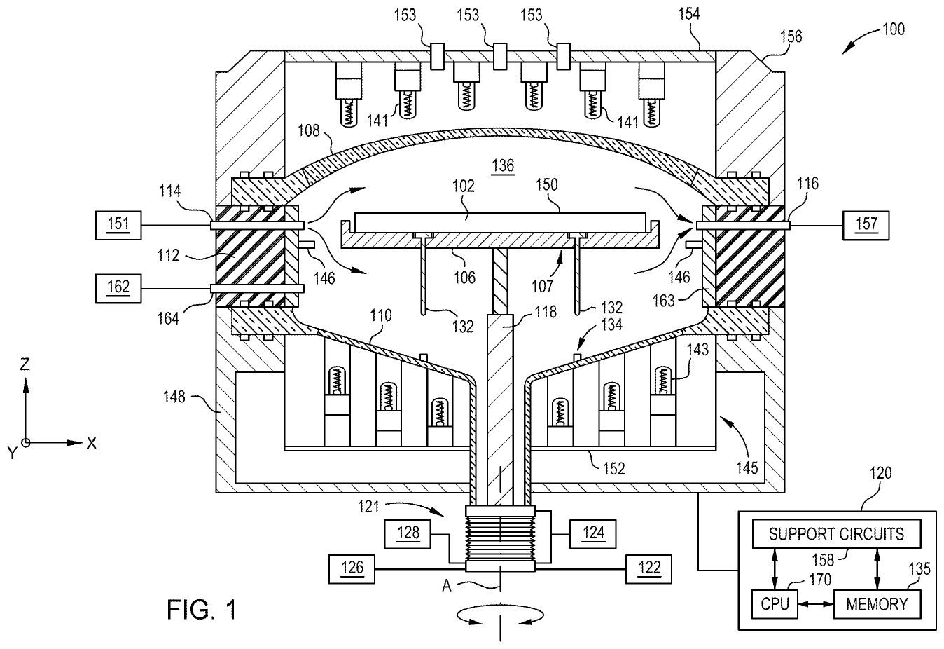

FIG. 1 is a schematic illustration of a type of deposition chamber 100 according to one implementation of the present disclosure. The deposition chamber 100 is utilized to grow an epitaxial film on a substrate, such as the substrate 102. The deposition chamber 100 creates a cross-flow of precursors across the top surface 150 of the substrate 102.

The deposition chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper dome 108, a lower dome 110, a plurality of upper lamps 141, and a plurality of lower lamps 143. The substrate support 106 is disposed between the upper dome 108 and the lower dome 110. The plurality of upper lamps 141 are disposed between the upper dome 108 and a lid 154. The lid 154 includes a plurality of sensors 153 disposed therein for measuring the temperature within the deposition chamber 100. The plurality of lower lamps 143 are disposed between the lower dome 110 and a floor 152. The plurality of lower lamps 143 form a lower lamp assembly 145.

A processing region 136 is formed between the upper dome 108 and the lower dome 110. The processing region 136 has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment of the shaft 118 and/or the substrate support 106 within the processing region 136. The motion assembly 121 includes a rotary actuator 122 that rotates the shaft 118 and/or the substrate support 106 about a longitudinal axis A of the deposition chamber 100. The motion assembly 121 further includes a vertical actuator 124 to lift and lower the substrate support 106 in the z-direction. The motion assembly 121 includes a tilt adjustment device 126 that is used to adjust the planar orientation of the substrate support 106 and a lateral adjustment device 128 that is used to adjust the position of the shaft 118 and the substrate support 106 side to side within the processing region 136.

The substrate support 106 may include lift pin holes 107 disposed therein. The lift pin holes 107 are sized to accommodate a lift pin 132 for lifting of the substrate 102 from the substrate support 106 either before or after a deposition process is performed. The lift pins 132 may rest on lift pin stops 134 when the substrate support 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 102 disposed within the processing region 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the processing region 136.

The deposition chamber 100 further includes a controller 120. The controller 120 can include a central processing unit (CPU) 170, memory 135, and support circuits (or I/O) (not shown). The CPU 170 may be one of any form of computer processors that are used in industrial settings for controlling various processing and hardware (e.g., process gas delivery, purge gas delivery, and other hardware) and monitor the processes (e.g., processing time, susceptor and/or substrate position, power to the lamp assemblies). The memory 135 is connected to the CPU 170, and may be one or more of readily available memory, such as random access memory (RAM), read only memory (ROM), floppy disk, hard disk, or any other form of digital storage, local or remote. Software instructions and data can be coded and stored within the memory 135 for instructing the CPU 170. The support circuits 158 are also connected to the CPU 170 for supporting the processor in a conventional manner. The support circuits 158 may include conventional cache, power supplies, clock circuits, input/out circuitry, subsystems, and the like. A program (or computer instructions) readable by the controller 120 determines which tasks are performable. The program may be software readable by the controller 120 and may include code to monitor and control (e.g., switch between), for example, the various gas sources (phosphorous-containing source gas, the one or more deposition gases, the n-type dopant gas).

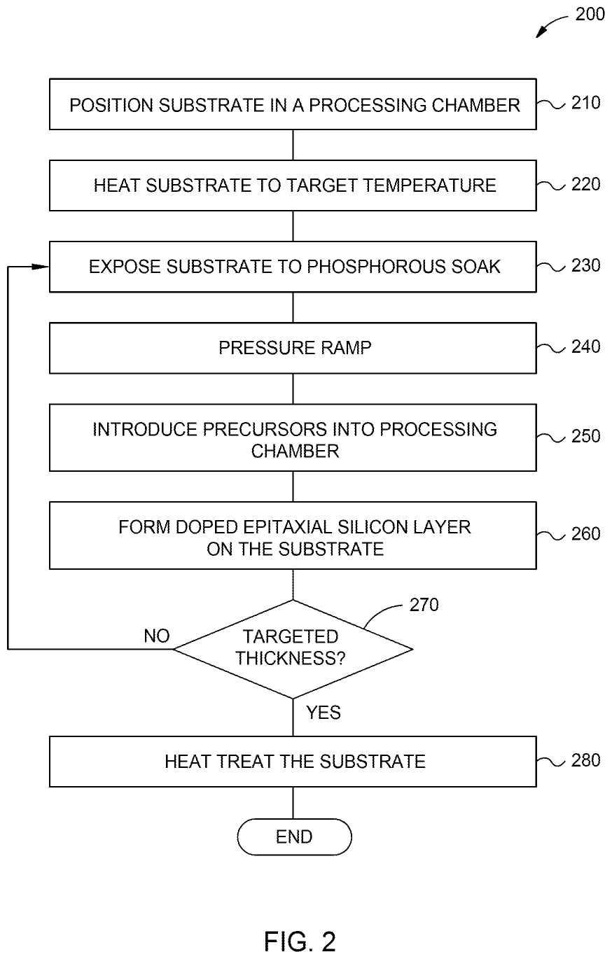

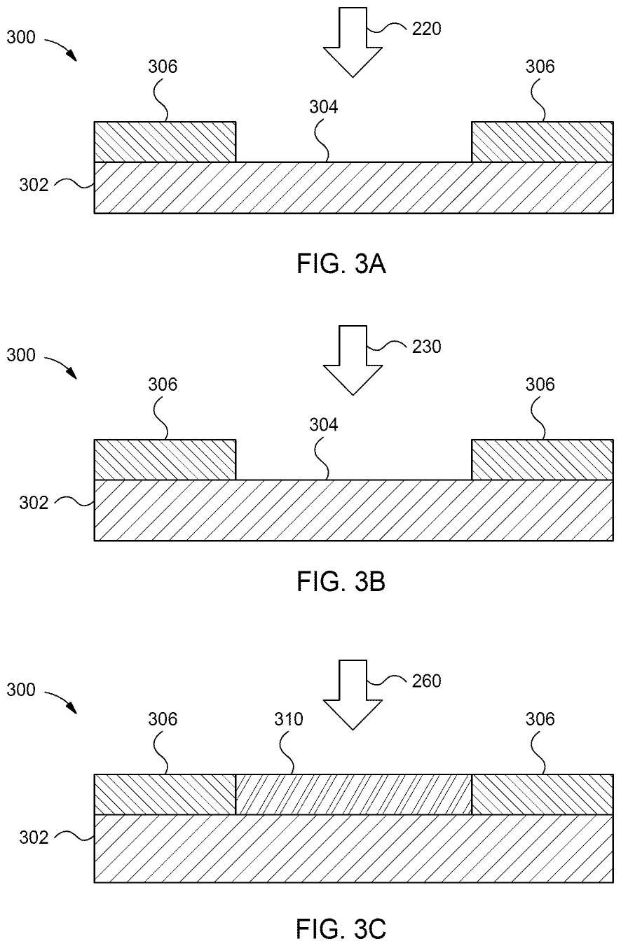

FIG. 2 illustrates a flow chart of a method 200 for manufacturing a semiconductor device in accordance with one or more implementations of the present disclosure. FIGS. 3A-3C illustrate views of various stages of manufacturing a semiconductor device in accordance with one or more implementations of the present disclosure. Although FIGS. 3A-3C are described in relation to the method 200, it will be appreciated that the structures disclosed in FIGS. 3A-3C are not limited to the method 200, but instead may stand alone as structures independent of the method 200. Similarly, although the method 200 is described in relation to FIGS. 3A-3C, it will be appreciated that the method 200 is not limited to the structures disclosed in FIGS. 3A-3C but instead may stand alone independent of the structures disclosed in FIGS. 3A-3C. It should be understood that FIGS. 3A-3C illustrate only partial schematic views of the semiconductor device 300, and the semiconductor device 300 may contain any number of transistor sections and additional materials having aspects not illustrated in the figures. It should also be noted that although the method 200 illustrated in FIG. 2 is described sequentially, other process sequences that include one or more operations that have been omitted and/or added, and/or has been rearranged in another desirable order, fall within the scope of the implementations of the disclosure provided herein.

Referring to FIG. 3A, at operation 210, a semiconductor device, for example, the semiconductor device 300 is positioned within a processing chamber. The processing chamber may be an epitaxial deposition chamber, for example, the deposition chamber 100 depicted in FIG. 1. In some implementations, the semiconductor device 300 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. FIGS. 3A-3C have been simplified for the sake of clarity to better understand the implementations of the present disclosure. Additional features can be added in the semiconductor device 300, and some of the features described below can be replaced, modified, or eliminated in other implementations of the semiconductor device 300.

The semiconductor device 300 includes a device substrate 302 as depicted in FIG. 3A. It is contemplated that the device substrate 302 may be a planar substrate or a patterned substrate. Patterned substrates are substrates that include electronic features formed into or onto a processing surface of the substrate. The device substrate 302 may contain monocrystalline surfaces 304 and/or one or more secondary surfaces 306 that are non-monocrystalline, such as polycrystalline or amorphous surfaces. The secondary surface 306 may be, for example, a patterned dielectric. Monocrystalline surfaces include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces. It is understood that the device substrate 302 may include multiple layers, or include, for example, partially fabricated devices such as transistors, flash memory devices, and the like.

The device substrate 302 may further include integrated circuit devices (not shown). For example, the device substrate 302 may further include FinFET transistors in addition to interconnect structures. As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device 300.

Referring to FIG. 3A, at operation 220, the device substrate 302 is heated to a target temperature. The target temperature is below the thermal budget of the semiconductor device 300, for example, a temperature of 500 degrees Celsius or less or a temperature of 480 degrees Celsius or less. In at least one aspect, the temperature in the processing chamber may be adjusted so that a reaction region formed at or near an exposed surface of the semiconductor device 300, or that the surface of the semiconductor device 300, is about 500 degrees Celsius or less, or about 480 degrees Celsius or less, or about 450 degrees Celsius or less, or about 400 degrees Celsius or less, or about 350 degrees Celsius or less. In one example, the substrate is heated to a temperature in a range from about 350 degrees Celsius to about 500 degrees Celsius, or in a range from about 350 degrees Celsius to about 480 degrees Celsius, or in a range from about 350 degrees Celsius to about 400 degrees Celsius, or in a range from about 400 degrees Celsius to about 480 degrees Celsius. Not to be bound by theory but in some implementations where Si: Sb, Si: P, or Si: Sb: P is formed, deposition at temperatures below 350 degrees Celsius has a very slow growth rate and deposition at temperatures greater than 500 degrees Celsius may affect the thermal budget of other materials formed on the semiconductor device 300. It is possible to minimize the thermal budget of the final device by heating the substrate to the lowest temperature sufficient to thermally decompose process reagents and epitaxially deposit a layer on the substrate.

Referring to FIG. 3B, at operation the device substrate 302 is exposed to a phosphorous soak process, for example, a phosphine soak process. The phosphorous soak process is performed by flowing a phosphorous-containing source gas into the processing region. Not to be bound by theory but it is believed that the phosphorous soak process incorporates an appropriate amount of phosphorous dopant to reduce film resistivity, which may lead to improved mobility or improved activation. An overdosed phosphorous soak can poison the film and prevent subsequent growth of the doped epitaxial film. Thus, an optimization of process conditions such as soak time and soak partial pressure is desirable to achieve an appropriate tradeoff between growth rate and resistivity. In some implementations, the substrate surface is exposed to a phosphorous soak process at the temperature established during operation 220, for example, a temperature of 500 degrees Celsius or less. The phosphorous soak process is typically performed at a first pressure within a range from about 10 Torr to about 100 Torr, or in a range from about 20 Torr to about 100 Torr, or in a range from about 30 Torr to about 80 Torr, or in a range from about 40 Torr to about 70 Torr. Not to be bound by theory but it is believed that at pressures greater than 100 Torr, surface poisoning, which prevents growth of the subsequently deposited doped epitaxial silicon layer. The soak is usually conducted to the substrate surface for a period of time in the range from about 20 seconds to about 90 seconds. In one aspect, the soak will last for about 70 seconds or less. In another aspect, the soak will last for about 50 seconds or less. In another aspect, the soak will last for about 20 seconds. However, the period of time for the soak process may be adjusted based on the pressure at which the soak process is performed. The flow rate of phosphine gas is generally in the range from about 10 sccm to about 2,000 sccm, preferably from about 50 sccm to about 500 sccm. In at least one implementation, the phosphorous-containing source gas includes one or a combination of phosphine source gas, phosphorous halide source gases, and organic phosphorous source gases, for example, alkylphosphines. Phosphorous halide source gases may include compounds with the formula PH(3-x)X′x where H is hydrogen, X′ is a halogen such as CI, F, Br, or I, and x=1, 2, or 3. Suitable examples of phosphorous halide source gases include PCI3. Organic phosphorous source gases may include alkylphosphine compounds with the formula RxPH(3-x), where R is methyl, ethyl, propyl, or butyl, H is hydrogen, and x=1, 2, or 3. Suitable alkylphosphines include trimethylphosphine ((CH₃)₃P), dimethylphosphine ((CH₃)₂PH), triethylphosphine ((CH₃CH₂)₃P), tert-butylphosphine, and diethylphosphine ((CH₃CH₂)₂PH). In at least one particular implementation, phosphine is used.

The phosphorous-containing source gas may be provided along with a carrier gas. The carrier gas may have a flow rate in a range from about 1 SLM to about 100 SLM or in a range from about 3 SLM to about 30 SLM. Suitable carrier gases include nitrogen (N2), hydrogen (H2), argon, helium, or combinations thereof. The carrier gas may be selected based on the reactants used and/or the process temperature during the soak process.

At operation 240, pressure in the processing region is increased from the first pressure of the phosphorous soak process to a second pressure suitable for growth of the doped epitaxial silicon layer at operation 260. The pressure increase or pressure ramp-up may be achieved by flowing an inert gas into the processing region, by sudden change (e.g., opening or closing of a throttle valve or other valve), or both flowing an inert gas and sudden change. The second pressure can be 150 Torr or greater, for example, in a range from about 150 Torr to about 300 Torr. The pressure ramp-up process of operation 240 purges or removes any phosphorous gas remaining from the soak process from the processing region.

At operation 250, one or more processing reagents are introduced into the processing region. The one or more processing regents may be introduced in the processing region concurrently or sequentially in the form of a gas mixture or separated gas mixtures. The one or more processing reagents include one or more deposition gases and at least one n-type dopant gas. The deposition gas includes one or more chlorosilane precursor gases and optionally one or more silicon precursor gases selected from silane gas, a higher order silane precursor gas, or a combination of a silane gas and a chlorosilane precursor gas. Higher order silanes include silanes with the chemical formula SiₓH₍₂ₓ₊₂₎ where x is 2 or more, for example, where x is 2, 3, 4, 5, 6, 7, 8, or more. Examples of higher order silanes include disilane (Si₂H₆), trisilane (Si₃H₈), and tetrasilane (Si₄H₁₀), or other higher order silanes. Chlorosilanes include chlorosilanes with the chemical formula Cl_{y}SiₓH_{(2x+2-y)} wherein y is 1 or more, 2 or more, 3 or more, or 5 or more, and x is one or more, or two or more, or 3 or more. In one example, y is from 5 to 8 and x is from 2 to 3. In at least one implementation, the second chlorosilane precursor gas comprises, consists of, or consists essentially of chlorosilane (ClSiH3), dichlorosilane (Cl2SiH2; DCS), trichlorosilane (Cl3SiH; TCS), hexachlorodisilane (Si₂Cl₆), tetrachlorosilane (SiCl₄), pentachlorodisilane (Cl₅Si₂H), octachlorotrisilane (Cl₈Si₃), or a combination thereof. In one example, the deposition gas is introduced into the processing region at a flow rate in a range from about 1 sccm to about 500 sccm, or in a range from about 10 sccm to about 400 sccm, or in a range from about 50 sccm to about 300 sccm, or in a range from about 100 sccm to about 200 sccm. In one implementation, the deposition gas includes TCS and DCS. In another implementation, the deposition gas includes TCS and silane. In yet another implementation, the deposition gas includes silane, DCS, and TCS. In one example, the deposition gas includes introducing silane gas into the processing region at a flow rate in a range from about 100 sccm to about 500 sccm, introducing dichlorosilane gas into the processing region at a flow rate in a range from about 500 sccm to about 1000 sccm, and introducing TCS in a hydrogen carrier at a total flow rate in a range from about 3000 sccm to about 9000 sccm.

In at least one aspect, the n-type dopant precursor comprises, consists of, or essentially consists of a phosphorous containing precursor, an antimony precursor, or a combination thereof. In at least one implementation, the antimony-containing precursor includes one or a combination of stibine, antimony trichloride, antimony tetrachloride, antimony pentachloride, triphenylantimony, antimony trihydide, antimony trifluoride, antimony tribromide, antimonytriiodide, antimony pentafluoride, triethyl antimony, and trimethyl antimony. In at least one implementation, the phosphorous-containing precursor includes one or a combination of phosphine and alkylphosphines. Suitable alkylphosphines include trimethylphosphine ((CH₃)₃P), dimethylphosphine ((CH₃)₂PH), triethylphosphine ((CH₃CH₂)₃P), tert-butylphosphine, and diethylphosphine ((CH₃CH₂)₂PH). In at least one particular implementation, phosphine is used. The n-type dopant precursor gas may have a flow rate in a range from about 0.1 sccm and 10,000 sccm, or in a range from about 100 sccm to about 5,000 sccm, or in a range from about 500 to about 3,000 sccm, or in a range from about 500 sccm to about 1,000 sccm. In at least one particular implementation, the n-type dopant precursor is triethyl antimony. In one or more implementations, the chlorosilane gas has a flow rate in a range from about 500 sccm to about 1,000 sccm and the antimony-containing source gas has a flow rate in a range from about 500 sccm to about 1,000 sccm.

In one or more implementations, the silicon source gas includes TCS and DCS and the n-type dopant precursor is triethyl antimony.

The processing reagents may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. The carrier gas may have a flow rate from about 1 SLM (standard liters per minute) to about 100 SLM, such as from about 3 SLM to about 30 SLM.

Referring to FIG. 3C, at operation 260, the mixture of reagents is thermally reacted to form an antimony doped silicon epitaxial layer 310 on the device substrate 302. The antimony doped silicon epitaxial layer 310 is selectively formed on the monocrystalline surfaces 304 relative to the secondary surfaces 306. During operation 260, the temperature within the processing region is maintained at a temperature of about 500 degrees Celsius or less or a temperature of about 480 degrees Celsius or less. The pressure within the processing region is maintained at the second pressure established during the pressure ramp of operation 240. The second pressure within the processing chamber is maintained at about 150 Torr or greater, for example, about 150 Torr to about 300 Torr. Not to be bound by theory, but it has been observed that by increasing the pressure to about 150 Torr or greater, the deposited epitaxial film can be formed with a greater level of N-dopant, for example, about 3×10²¹ atoms per cubic centimeter as compared to epitaxial growth processes including an etchant gas.

The antimony doped silicon epitaxial layer 310 may have a thickness within a range from about 10 angstrom to about 500 angstroms, for example, within a range from about 50 to about 500, or within a range from about 100 angstrom to about 400 angstroms, or within a range from about 100 angstroms to about 300 angstroms, or within a range from about 200 angstroms to about 300 angstroms, or within a range from about 100 angstroms to about 200 angstroms.

At operation 270 it is determined whether a targeted thickness of the antimony doped silicon epitaxial layer 310 has been achieved. If the targeted thickness has not been achieved, the method 200 may return to operation 230 to perform an additional phosphorous soak process followed by operations 240-270 to increase the thickness of the antimony doped silicon epitaxial layer 310. Not to be bound by theory, but it is believed that the phosphorous soaked surface provided by the phosphorous soak process of operation 230 last for approximately 50 to 90 angstroms of growth of the antimony doped silicon layer and then the phosphorous soak process may be repeated in order to maintain growth of the antimony doped silicon. If the targeted thickness has been achieved, the semiconductor device 300 may be subjected to additional processing, for example, the heat treatment of operation 280.

Optionally, after operation 260, operation 270, or both operation 260 and operation 270, the semiconductor device 300 including the device substrate 302 and the antimony doped silicon epitaxial layer 310 is thermally heat treated at operation 280 to activate the dopants. In one or more implementations, the thermal treatment of the semiconductor device 500 is a spike anneal process. The spike anneal process is performed at temperatures in a range from about 800 degrees Celsius to about 1200 degrees Celsius, or in a range from about 850 degrees Celsius to about 950 degrees Celsius. The spike anneal process may be performed for a time period from about 1 second to about 30 seconds. The spike anneal process has been found to improve resistivity of the formed semiconductor device 500.

In one or more implementations, the thermal treatment of operation 280 includes exposing the semiconductor device 500 to rapid high temperature anneal pulses. The rapid high temperature anneal pulses are dynamic surface anneal (DSA) pulses, such that laser pulses are applied to the surface of the semiconductor device 500 using a laser source. The laser pulses may be performed in a laser annealing chamber, such as a DSA chamber. The DSA process may be a scanning DSA process and may be performed in a scanning DSA chamber. The DSA process may be a millisecond anneal process, which includes heating the substrate to a temperature in a range from about 800° C. to about 1,300° C., or in a range from about 1,000° C. to about 1,300° C., or in a range from about 1,000° C. to about 1,200° C., or about 1,150° C. to about 1,200° C. for a period of about 0.05 milliseconds to about 5 milliseconds, about 0.1 milliseconds to about 2 milliseconds, about 0.2 millisecond to about 1 millisecond, or about 0.5 millisecond to about 1 millisecond.

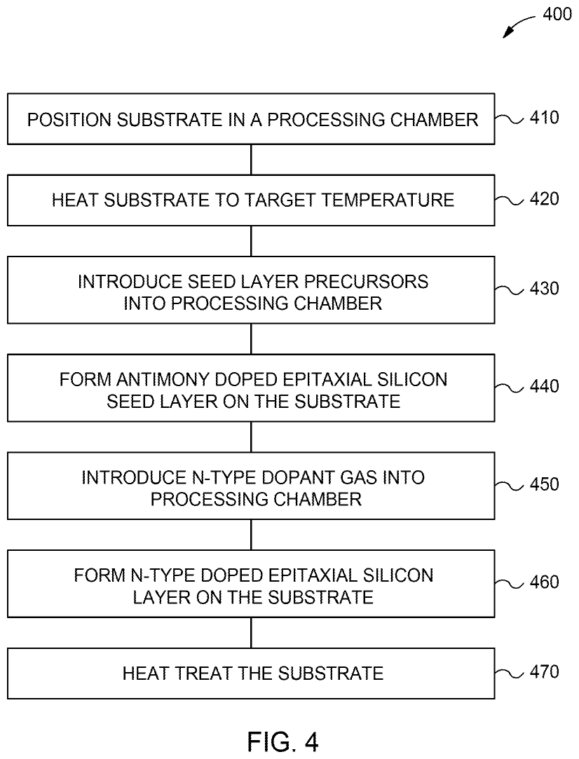

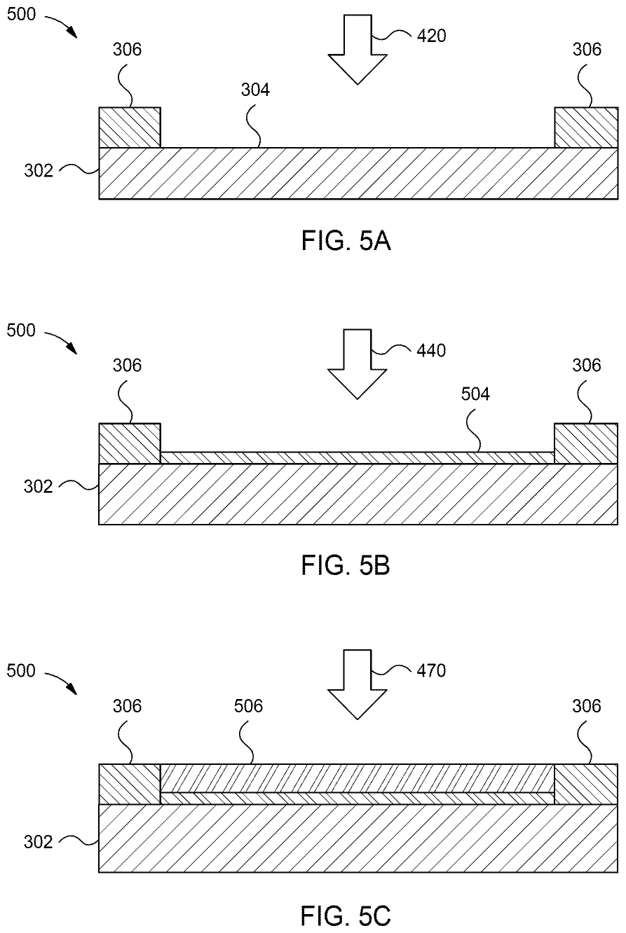

FIG. 4 illustrates a flow chart of a method 400 for manufacturing a semiconductor device in accordance with one or more implementations of the present disclosure. FIGS. 5A-5C illustrate views of various stages of manufacturing a semiconductor device in accordance with one or more implementations of the present disclosure. Although FIGS. 5A-5C are described in relation to the method 400, it will be appreciated that the structures disclosed in FIGS. 5A-5C are not limited to the method 400, but instead may stand alone as structures independent of the method 400. Similarly, although the method 400 is described in relation to FIGS. 5A-5C, it will be appreciated that the method 400 is not limited to the structures disclosed in FIGS. 5A-5C but instead may stand alone independent of the structures disclosed in FIGS. 5A-5C. It should be understood that FIGS. 5A-5C illustrate only partial schematic views of the semiconductor device 500, and the semiconductor device 500 may contain any number of transistor sections and additional materials having aspects not illustrated in the figures. It should also be noted that although the method 400 illustrated in FIG. 4 is described sequentially, other process sequences that include one or more operations that have been omitted and/or added, and/or has been rearranged in another desirable order, fall within the scope of the implementations of the disclosure provided herein.

Referring to FIG. 5A, at operation 410, a semiconductor device, for example, the semiconductor device 500 is positioned within a processing chamber. The semiconductor device 500 may be similar to the semiconductor device 300 as previously described. The processing chamber may be an epitaxial deposition chamber, for example, the deposition chamber 100 depicted in FIG. 1. The semiconductor device 500 includes the device substrate 302 as depicted in FIG. 5A.

Referring to operation 420, the device substrate 302 is heated to a target temperature. The device substrate 302 may be as described in operation 210. The target temperature is below the thermal budget of the semiconductor device 500, for example, a temperature of 500 degrees Celsius or less or a temperature of 480 degrees Celsius or less. The target temperature may be as described in operation 220.

At operation 430, one or more processing reagents including seed layer precursors are introduced into the processing chamber. The one or more seed layer precursors may be introduced in the processing region concurrently or sequentially in the form of a gas mixture or separated gas mixtures. The one or more seed layer precursors include one or more deposition gases and at least one antimony containing gas. The deposition gas includes one or more chlorosilane precursor gases and may include one or more silicon precursor gases selected from silane, a higher order silane precursor gas, or a combinations of silane and a higher order silane precursor gas. Higher order silanes include silanes with the chemical formula SiₓH₍₂ₓ₊₂₎ where x is 2 or more, for example, where x is 2, 3, 4, 5, 6, 7, 8, or more. Examples of higher order silanes include disilane (Si₂H₆), trisilane (Si₃H₈), and tetrasilane (Si₄H₁₀), or other higher order silanes. Chlorosilanes include chlorosilanes with the chemical formula Cl_{y}SiₓH_{(2x+2-y)} wherein y is 1 or more, 2 or more, 3 or more, or 5 or more, and x is one or more, or two or more, or 3 or more. In one example, y is from 5 to 8 and x is from 2 to 3. In at least one implementation, the second chlorosilane precursor gas comprises, consists of, or consists essentially of chlorosilane (ClSiH3), dichlorosilane (Cl2SiH2; DCS), trichlorosilane (Cl3SiH; TCS), hexachlorodisilane (Si₂Cl₆), tetrachlorosilane (SiCl₄), pentachlorodisilane (Cl₅Si₂H), octachlorotrisilane (Cl8Si3), or a combination thereof. In one example, the deposition gas is introduced into the processing region at a flow rate in a range from about 1 sccm to about 500 sccm, or in a range from about 10 sccm to about 400 sccm, or in a range from about 50 sccm to about 300 sccm, or in a range from about 100 sccm to about 200 sccm. In one implementation, the silicon precursor gas includes TCS and DCS. In another implementation, the silicon precursor gas includes TCS and silane. In yet another implementation, the deposition gas includes silane, DCS, and TCS. In one example, the deposition gas includes introducing silane gas into the processing region at a flow rate in a range from about 100 sccm to about 500 sccm, introducing dichlorosilane gas into the processing region at a flow rate in a range from about 500 sccm to about 1000 sccm, and introducing TCS in a hydrogen carrier at a total flow rate in a range from about 3000 sccm to about 9000 sccm.

In at least one implementation, the antimony-containing precursor includes one or a combination of stibine, antimony trichloride, antimony tetrachloride, antimony pentachloride, triphenylantimony, antimony trihydide, antimony trifluoride, antimony tribromide, antimonytriiodide, antimony pentafluoride, triethyl antimony, and trimethyl antimony. In at least one particular implementation, phosphine is used. The antimony containing precursor gas may have a flow rate in a range from about 0.1 sccm and 10,000 sccm, or in a range from about 100 sccm to about 5,000 sccm, or in a range from about 500 to about 3,000 sccm, or in a range from about 500 sccm to about 1,000 sccm. In one implementation, the antimony containing precursor is triethyl antimony.

The one or more processing reagents including seed layer precursors comprise, consists of, or consists essentially of one or more silicon precursor gases and one or more antimony containing precursors. In one or more implementations, the one or more processing reagents for forming the seed layer are free from phosphorous-containing gases or substantially-free from phosphorous-containing gases meaning that trace amounts of phosphorous-containing gases may be present, for example, less than 1% of the total gas mixture.

The processing reagents form forming the seed layer may optionally include a carrier gas. The carrier gas may be selected based on the precursor(s) used and/or the process temperature during the epitaxial process. Suitable carrier gases include nitrogen, hydrogen, argon, helium, or other gases which are inert with respect to the epitaxial process. The carrier gas may have a flow rate from about 1 SLM (standard liters per minute) to about 100 SLM, such as from about 3 SLM to about 30 SLM.

Referring to FIG. 5B, at operation 440, the mixture of reagents is thermally reacted to form an antimony doped silicon epitaxial seed layer 504 on the device substrate 302. The antimony doped silicon epitaxial seed layer 504 is selectively formed on the monocrystalline surfaces 304 with minimal to no growth on the secondary surfaces 306. During operation 440, the temperature within the processing region is maintained at a temperature of about 500 degrees Celsius or less or a temperature of about 480 degrees Celsius or less. The pressure within the processing region may be maintained at about 150 Torr or greater, for example, about 150 Torr to about 300 Torr. The antimony doped silicon epitaxial seed layer 504 may have a thickness within a range from about 1 angstrom to about 100 angstroms, for example, within a range from about 1 to about 30, or within a range from about 1 angstrom to about 20 angstroms, or within a range from about 3 angstroms to about 20 angstroms, or within a range from about 3 angstroms to about 10 angstroms, or within a range from about 10 angstroms to about 20 angstroms, or within a range from about 5 angstroms to about 10 angstroms.

At operation 450, an N-type dopant gas is introduced into the processing chamber. The N-type dopant gas is generally introduced into the processing chamber while continuing to flow the one or more silicon-containing deposition gases and the at least one antimony containing gas into the processing chamber. In at least one implementation, the N-type dopant gas is a phosphorous-containing source gas. In at least one implementation, the phosphorous-containing source gas includes one or a combination of phosphine source gas, phosphorous halide source gases, and organic phosphorous source gases, for example, alkylphosphines. In at least one particular implementation, phosphine is used. The flow rate of the phosphorous-containing precursor gas is generally in the range from about 1 sccm to about 2,000 sccm, or in a range from about 1 sccm to about 100 sccm, or in a range from about 1 sccm to about 50 sccm, or in a range from about 1 sccm to about 30 sccm, or in a range from about 10 sccm to about 30 sccm.

Referring to FIG. 5C, at operation 460, the mixture of reagents is thermally reacted to form an n-type doped silicon epitaxial layer 506 on the seed layer 504. The n-type doped silicon epitaxial layer 506 is selectively formed on the antimony doped silicon epitaxial seed layer 504 with minimal to no growth on the secondary surfaces 306. During operation 460, the temperature within the processing region is maintained at a temperature of about 500 degrees Celsius or less or a temperature of about 480 degrees Celsius or less. The pressure within the processing region may be maintained at about 150 Torr or greater, for example, about 150 Torr to about 300 Torr. The n-type doped silicon epitaxial layer 506 may have a thickness within a range from about 1 angstrom to about 100 angstroms, for example, within a range from about 1 to about 50, or within a range from about 1 angstrom to about 40 angstroms, or within a range from about 3 angstroms to about 30 angstroms, or within a range from about 3 angstroms to about 20 angstroms, or within a range from about 10 angstroms to about 20 angstroms, or within a range from about 5 angstroms to about 10 angstroms.

Optionally, after operation 460, the semiconductor device 500 including the device substrate 302, the antimony doped silicon epitaxial seed layer 504, and the n-type doped silicon epitaxial layer 506 is thermally heat treated at operation 470 to activate the dopants. In one or more implementations, the thermal treatment of the semiconductor device 500 can be a spike anneal process or a DSA process. The thermal heat treatment of operation 470 can be performed similarly to the thermal heat treatment described in operation 280.

The previously described implementations of the present disclosure have many advantages, including the following. The etchant-free deposition method described has improved throughput compared to conventional cyclic deposition and etch processes. The etch-free process described is more compatible with various chambers in mass production. The absence of etchant gas in the etchant-free process described enables deposition of an epitaxial film with a high level of dopant, for example, an N-type dopant concentration of greater than 3×10²¹ atoms per cubic centimeter, which is beneficial for resistivity tuning. The improved selectively of the etchant-free process described widens the process window tuning, thus increasing adaptability and feasibility. However, the present disclosure does not require that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A method of forming a film on a substrate, comprising:
heating a substrate disposed within a processing chamber to a temperature in a range from about 350 degrees Celsius to about 500 degrees Celsius;
exposing the substrate to a soak process in a phosphorous source gas at a first chamber pressure for a period of time;
increasing the first chamber pressure to a second chamber pressure; and
exposing the substrate to a deposition gas mixture comprising a chlorosilane gas and an antimony-containing source gas to deposit a silicon-containing epitaxial layer comprising antimony on the substrate.

2. The method of claim 1, wherein the first chamber pressure is within a range from about 20 Torr to about 100 Torr and the second chamber pressure is within a range from about 150 Torr to about 300 Torr.

3. The method of claim 2, wherein increasing the first chamber pressure to the second chamber pressure purges the phosphorous source gas from the processing chamber.

4. The method of claim 1, wherein the period of time is within a range from about 20 seconds to about 90 seconds.

5. The method of claim 1, wherein the phosphorous source gas is phosphine gas.

6. The method of claim 5, wherein the chlorosilane gas comprises dichlorosilane, trichlorosilane, or a combination thereof.

7. The method of claim 6, wherein the deposition gas mixture further comprises silane, disilane, or combination thereof.

8. The method of claim 1, further comprising repeating exposing the substrate to the soak process, increasing the first chamber pressure to the second chamber pressure, and exposing the substrate to the deposition gas mixture until a targeted thickness of the silicon-containing epitaxial layer is achieved.

9. The method of claim 1, further comprising:
flowing the chlorosilane gas at a flow rate in a range from about 500 sccm to about 1,000 sccm; and
flowing the antimony-containing source gas at a flow rate in a range from about 500 sccm to about 1,000 sccm.

10. A method of forming a film on a substrate, comprising:
heating a substrate disposed within a processing chamber to a temperature in a range from about 350 degrees Celsius to about 500 degrees Celsius;
exposing the substrate to a deposition gas mixture comprising a chlorosilane gas and an antimony-containing source gas to deposit an antimony doped silicon-containing epitaxial seed layer comprising antimony on the substrate;
introducing a phosphorous source gas into the processing chamber; and
exposing the substrate to the deposition gas mixture and the phosphorous source gas to deposit a silicon-containing epitaxial layer comprising antimony and phosphorous on the substrate.

11. The method of claim 10, wherein the antimony doped silicon-containing epitaxial seed layer has a thickness in a range from about 1 angstroms to about 100 angstroms.

12. The method of claim 10, wherein the antimony-containing source gas is one or a combination of stibine, antimony trichloride, antimony tetrachloride, antimony pentachloride, triphenylantimony, antimony trihydride, antimonytrioxide, antimony pentoxide, antimony trifluoride, antimony tribromide, antimonytriiodide, antimony pentafluoride, triethyl antimony, and trimethyl antimony.

13. The method of claim 10, further comprising:
flowing the chlorosilane gas in a carrier gas at a total flow rate in a range from about 3,000 to about 9,000 sccm;
flowing the antimony-containing source gas at a flow rate in a range from about 500 sccm to about 1,000 sccm; and
flowing the phosphorous source gas at a flow rate in a range from about 1 to about 2,000 sccm.

14. A method of forming an epitaxial film on a substrate, comprising:
positioning a substrate into a processing chamber, the substrate comprising a silicon surface and a dielectric surface;
exposing the substrate to a phosphorous source gas at a temperature in a range from about 350 degrees Celsius to about 500 degrees Celsius at a first chamber pressure within a range from about 20 Torr to about 100 Torr for a period of time;
increasing the first chamber pressure to a second chamber pressure; and
exposing the substrate to a deposition gas mixture comprising a chlorosilane gas and an antimony-containing source gas to selectively deposit a silicon-containing epitaxial layer comprising antimony on the silicon surface.

15. The method of claim 14, wherein the silicon-containing epitaxial layer has an antimony dopant concentration of greater than 3×10²¹ atoms per cubic centimeter.

16. The method of claim 14, wherein the second chamber pressure is within a range from about 150 Torr to about 300 Torr.

17. The method of claim 16, wherein increasing the first chamber pressure to the second chamber pressure purges the phosphorous source gas from the processing chamber.

18. The method of claim 14, wherein the period of time is within a range from about 20 seconds to about 90 seconds.

19. The method of claim 18, wherein the phosphorous source gas is phosphine gas and the chiorosilane gas comprises dichlorosilane, trichlorosilane, or a combination thereof.

20. The method of claim 19, wherein the deposition gas mixture further comprises silane, disilane, or combination thereof.
